(19) United States
(12) Patent Application Publication
(10) Pub. No.: US 2023/0414030 A1
(43) Pub. Date: Dec. 28, 2023

(54) FILTER CUP AND GRINDER

(71) Applicant: Breville Pty Limited, Alexandria, NSW (AU)

(72) Inventors: Lochana Subasekara WIDANAGAMAGE DON, Alexandria, NSW (AU); Xiang REN, Alexandria, NSW (CN); Con PSAROLOGOS, Alexandria, NSW (AU)

(21) Appl. No.: 18/035,330

(22) PCT Filed: Nov. 4, 2021
(86) PCT No.: PCT/AU2021/051299

§ 371 Date: May 4, 2023

(30) Foreign Application Priority Data
Nov. 4, 2020 (AU) 2020904019
Mar. 10, 2021 (AU) 2021900674

(51) Int. Cl. A47J 31/06; A47J 31/42; A47J 31/52

(52) U.S. Cl. CPC A47J 31/0663; A47J 31/42; A47J 31/525

(57) ABSTRACT

A filter cup (100) holds ground coffee within a portafilter for attachment to an espresso machine to extract a dose of coffee. The filter cup (100) has a body (102) including a floor (104) with a plurality of perforations (106), a sidewall (108) extending upwardly from the floor (104) to a rim (110) to define a cavity for holding the ground coffee, and a magnet (114) attached to the body (102) for producing a magnetic field.

### FIELD

The present invention relates to a filter cup and grinder.

### BACKGROUND

Modern espresso machines are adapted to produce espresso using a portafilter that holds a filter cup, the filter cup containing ground coffee and having a perforated floor to allow extracted coffee beverage to escape from the filter cup. To cater for different volumes of coffee beverage being produced, as well as different taste profiles of the extracted coffee beverage filter cups may have a variety of properties, such as different shapes, different design volumes of coffee grounds to be contained therein, and whether they are adapted to be used with freshly ground coffee, or pre-ground coffee. As a simplistic overview, a filter cup may be “single” size, or “double” size for production of a smaller coffee beverage or a larger coffee beverage. A filter cup may also be “single walled” and thus adapted to be used with freshly ground coffee, or “double walled” such that the possible pressure gradient between a cavity of the filter cup and the exterior of the filter cup is controlled, ensuring that a variety of pre-ground coffee may be adequately used in the filter cup.

A problem exists that the machine parameters of the espresso machine, such as coffee grind quantity and water quantity, must be adjusted when attempting to produce, for example, a larger beverage compared to a smaller beverage. This can be a complicated process and introduces user error, resulting in undesirable coffee outcomes.

A further problem exists that as the grinder operates, load fluctuations on the grinder caused by the discrete nature of coffee beans results in unpredictable flow amounts of coffee. Previous grinder control approaches use timers, or load cells reading a weight produced, which are imprecise and expensive to implement, respectively.

Yet a further problem exists when the grinder is grinding coffee beans in that determining whether the coffee bean hopper in the grinder is empty or almost empty can be inaccurate using current detection methods in either existing stand-alone grinders or existing espresso machines with built in coffee bean grinders.

### SUMMARY OF INVENTION

It is an object of the present invention to address or overcome the above disadvantage, or at least provide a useful alternative to the above-mentioned filter cups.

In a first aspect, the present invention provides a filter cup for holding ground coffee for use with a portafilter to extract coffee, the filter cup including a body having:
a floor with a plurality of perforations;
a sidewall extending upwardly from the floor to a rim to define a cavity for holding the ground coffee; and
a magnet attached to the body for producing a magnetic field.

Preferably, the magnet is attached to the floor.

Preferably, the magnet is attached to the sidewall.

Preferably, the magnet is attached to an outside surface of the sidewall.

Preferably, the body has a key adapted to engage, when the filter cup is mounted on the portafilter, a corresponding portafilter key on the portafilter such that the filter cup is mountable on the portafilter in a predetermined configuration.

Preferably, the key includes a flange portion of the rim that extends downwardly from the rim and the portafilter key includes a protrusion on the portafilter.

Preferably, the key includes a boss portion located on the sidewall and extending outwardly therefrom and the portafilter key includes a recess in the portafilter for receiving the boss portion.

Preferably, the boss portion includes the magnet.

Preferably, the magnet has a predetermined property that influences the magnetic field produced by the magnet, for matching a property of the filter cup to be determined by measuring the magnetic field and reference a predetermined look-up table or a predetermined threshold.

Preferably, the predetermined property includes one or more of:
a direction of a magnet axis of the magnet relative to a central axis of the filter cup; and
a strength of the magnet.

Preferably, the filter cup further comprises an enclosure for housing the magnet, the housing having a retainment space for receiving the magnet, and at least one flap for securing the enclosure to the filter cup. In a further prefered form, the flap is secured to the filter cup by spot welding.

In some embodiments, the body has a plurality of magnets.

In a second aspect, the present invention provides a portafilter holding the filter cup of the first aspect.

Preferably, the portafilter further includes:
a sensor for determining a magnitude and/or direction of the magnetic field produced by the magnet and adapted to produce a magnet signal indicative of the magnitude and/or direction of the magnetic field;
a portafilter processor adapted to:
   receive the magnet signal;
   determine a property of the filter cup based on the magnet signal; and
   produce a filter cup signal indicative of a property of the filter cup; and
a communication module adapted to:
   receive the filter cup signal; and
   transmit the filter cup signal to a receiver module.

Preferably, the sensor is a hall effect sensor.

Preferably, the sensor is a magnetometer.

In a third aspect, the present invention provides an espresso machine used with the portafilter of the second aspect.

Preferably, the espresso machine includes:
a sensor for determining a magnitude and/or direction of the magnetic field produced by the magnet and producing a magnet signal indicative of the magnitude and/or direction of the magnetic field;
a machine processor adapted to:
   receive the magnet signal;
   determine a property of the filter cup based on the magnet signal; and
   modify one or more of the following machine parameters based on the property of the filter cup:
      a ground coffee quantity;
      a brewing pressure setting or profile;
      a brewing temperature
      a pre-infusion period;
      a water quantity; and
      a water flow rate.

Preferably, the receiver module is mounted in the espresso machine and the espresso machine further includes:
a machine processor adapted to:
   receive the filter cup signal; and
   modify one or more of the following machine parameters of the espresso machine based on the filter cup signal:
      a ground coffee quantity;
      a brewing pressure setting or profile;
      a pre-infusion period;
      a water quantity; and
      a water flow rate.

Preferably, the espresso machine further includes:
a memory module in communication with the machine processor and containing a database of predetermined extraction profiles, each associated with a predetermined set of filter cup properties, each extraction profile containing information relating to one or more of the following machine parameters:
   a ground coffee quantity;
   a brewing pressure setting or profile;
   a pre-infusion period;
   a water quantity; and
   a water flow rate;

and wherein the machine processor is adapted to access the database and modify the machine parameters of the espresso machine to coincide with a particular extraction profile that corresponds to a particular filter cup property or set of properties determined by measuring the magnetic field produced by the magnet.

Preferably, the espresso machine includes a user interface in communication with the machine processor and the machine processor is adapted to modify the extraction profile based on a user input received at the user interface.

In a fourth aspect, the present invention provides a standalone grinder used with the portafilter of the second aspect.

In a fifth aspect, the present invention provides a grinder for manufacturing ground coffee from coffee beans, the grinder having:
a grinding element for grinding coffee beans to ground coffee;
a motor operable to drive the grinding element;
a controller adapted to control operation of the motor; and
a grinder position sensor for providing a position signal to the controller, the position signal being indicative of a position of the grinding element as the grinding element is driven by the motor,
wherein the controller operates the motor based on the position signal, and the controller determines whether a dose of coffee has been ground based on the position signal.

Preferably, the grinder position sensor includes a motor shaft position sensor and the position signal includes a signal width.

Preferably, the grinder position sensor is adapted to detect at least 1 rotary position of a motor shaft of the motor. For example, the grinder position sensor is adapted to detect 6 equally distributed rotary positions of a motor shaft of the motor.

Preferably, the grinder position sensor includes a hall effect sensor.

Preferably, the grinder further includes a motor current sensor for providing a motor current signal to the controller, the motor current signal being indicative of a current being drawn by the motor,

wherein the controller operates the motor based on the motor current signal and the position signal.

In a sixth aspect the present invention provides a method of manufacturing ground coffee using a grinder, the grinder having:
a grinding element for grinding coffee beans to ground coffee;
a motor operable to drive the grinding element;
a controller adapted to control operation of the motor; and
a grinder position sensor for providing a position signal to the controller, the position signal being indicative of a position of the grinding element as the grinding element is driven by the motor,
   wherein the method includes the steps of:
operating, using the processor, the motor at a first control set point to drive the grinding element;
determining, using the processor, a speed signal based on the position signal, the speed signal being indicative of an instantaneous speed of the grinding element;
determining, using the processor, a speed difference between the speed signal and a predetermined target speed;
determining, using the processor, a second control set point based on the speed difference;
operating, using the processor, the motor at the second control set point, and determining whether a dose of coffee has been ground based on the position signal.

Preferably, the position signal is indicative of a discrete position of the grinding element, selected from a plurality of discrete positions, and wherein the method further includes the steps of:
determining, using the processor, an instantaneous flow rate of ground coffee between a current discrete position and a previous discrete position of the grinding element;
recording, using the processor, the instantaneous flow rate of ground coffee to a set of recorded flow rates;
determining, using the processor, a total amount of ground coffee manufactured based on the set of recorded flow rates.

Preferably, the step of determining the instantaneous flow rate includes determining the instantaneous flow rate based on the speed difference.

Preferably, the step of determining the instantaneous flow rate includes:
determining, using the processor, if a magnitude of the speed difference is above a predetermined threshold; and
   if the speed difference is above the threshold, determining the instantaneous flow rate based on the speed difference, and
   if the speed difference is not above the threshold, assigning a predetermined constant as the instantaneous flow rate.

Preferably, the grinder further includes a motor current sensor for providing a motor current signal to the controller, the motor current signal being indicative of a current being drawn by the motor, and wherein the step of determining the instantaneous flow rate includes:
determining, using the processor, a magnitude of a motor current difference between the motor current signal and a predetermined target motor current;
determining, using the processor, if the magnitude of the motor current difference is above a predetermined threshold; and
   if the motor current difference is above the threshold, determining the instantaneous flow rate based on the motor current difference, and
   if the motor current difference is not above the threshold, assigning a predetermined constant as the instantaneous flow rate.

Preferably, the step of determining the instantaneous flow rate is at least partially based on one or more grinder properties selected from:
a grinder coarseness;
a grinder material; and
a geometric property of the grinder.

Preferably, the step of determining the total amount of ground coffee manufactured includes:
determining, using the processor, a total rotational distance travelled by the grinding element based on the position signal; and
determining, using the processor a target rotational distance based on a previous target rotational distance and the speed difference,
   and the method further includes the step of:
stopping, using the processor, the motor when the total rotational distance is equal to or larger than the target rotational distance.

Preferably, the processor determines the total rotational distance travelled by incrementing a motor turn counter based on the position signal; and

wherein the processor determines the target rotational distance by altering, based on the speed difference, a target motor turn count.

Preferably, the grinder position sensor includes a motor shaft position sensor.

Preferably, the method further includes the step of:
stopping, using the processor, the motor when the total amount of ground coffee manufactured is equal to or larger than a target dose.

In a seventh aspect, the present invention provides a grinder for manufacturing ground coffee from coffee beans, the grinder having:
a grinding element for grinding coffee beans to ground coffee;
a motor operable to drive the grinding element;
   a coffee bean hopper for providing coffee beans to the grinding element, and
a controller adapted to control operation of the motor;
wherein the controller is arranged to monitor a speed of the motor to determine a power control signal being applied to the motor, and
determine whether a coffee bean level in the coffee bean hopper is above or below a defined threshold value based on the determined power control signal over a determined period.

Preferably, the power control signal includes one or more of:
a pulse width modulation (PWM) duty cycle value or a phase angle value;
a pulse width modulation (PWM) duty cycle percentage value based on a motor power value determined by the controller;
a phase angle percentage value based on a motor power value determined by the controller;
a motor current value; and
a motor voltage value.

Preferably, the power control signal is determined by the controller by applying a proportion integral derivative (PID) calculation to the speed of the motor.

Preferably, the power control signal is determined by the controller to maintain the speed of the motor at a constant level.

Preferably, the controller is further adapted to:
determine an average value of the power control signal during a predetermined period of time;
compare the average value to a previous average value, wherein the previous average value is the average value from a previous predetermined period of time;
cease operation of the motor when the average value is lower than the previous average value for a plurality of subsequently determined average values.

Preferably, the controller is further adapted to:
reset a shutdown counter when commencing a grinding operation;
progressing the shutdown counter by an increment when the average value is lower than a previous average value; and
cease operation of the motor when shutdown counter reaches a predetermined threshold.

Preferably, the controller is further adapted to:
determine a minimum value and a maximum value of the power control signal during the predetermined period of time;
cease operation of the motor when:
   the average value is lower than the previous average value for a plurality of subsequently determined average values; and
   a difference between the maximum value and the minimum value is less than a predetermined threshold for a plurality of subsequently determined maximum and minimum value difference.

Preferably, the controller is arranged to monitor a voltage being applied to the motor and adjust the defined threshold value based on the monitored voltage.

Preferably, the controller is arranged to shut down upon determining that the coffee bean level in the coffee bean hopper is at, above or below the defined threshold value.

In an eighth aspect, the present invention provides an espresso machine comprising the grinder of the fifth aspect.

In a ninth aspect, the present invention provides a method for manufacturing ground coffee from coffee beans in a grinder, the method comprising the steps of:
grinding coffee beans to ground coffee using a motor operable to drive a grinding element;
providing coffee beans to the grinding element via a coffee bean hopper,
controlling operation of the motor;
monitoring a speed of the motor to determine a power control signal being applied to the motor, and
determining whether a coffee bean level in the coffee bean hopper is above or below a defined threshold value based on the determined power control signal.

Preferably, the power control signal includes one or more of:
a pulse width modulation (PWM) duty cycle value or a phase angle value;
a pulse width modulation (PWM) duty cycle percentage value based on a motor power value determined by the controller;
a phase angle percentage value based on a motor power value determined by the controller;
a motor current value; and
a motor voltage value.

Preferably, the power control signal is determined by the controller by applying a proportion integral derivative (PID) calculation to the speed of the motor.

Preferably, the power control signal is determined by the controller to maintain the speed of the motor at a constant level.

Preferably, the method further includes the steps of:
determining an average value of the power control signal during a predetermined period of time;
comparing the average value to a previous average value, wherein the previous average value is the average value from a previous predetermined period of time;
ceasing operation of the motor when the average value is lower than the previous average value for a plurality of subsequently determined average values.

Preferably, the method further includes the steps of:
resetting a shutdown counter when commencing a grinding operation;
progressing the shutdown counter by an increment when the average value is lower than the previous average value; and
ceasing operation of the motor when shutdown counter reaches a predetermined threshold.

Preferably, the method further includes the steps of:
determining a minimum value and a maximum value of the power control signal during the predetermined period of time;
ceasing operation of the motor when:
   the average value is lower than the previous average value for a plurality of subsequently determined average values; and
   a difference between the maximum value and the minimum value is less than a predetermined threshold for a plurality of subsequently determined maximum and minimum value difference.

Preferably, the method further comprises the step of monitoring a voltage being applied to the motor and adjusting the defined threshold value based on the monitored voltage.

Preferably, the method further comprises the step of shutting down the grinder upon determining that the coffee bean level in the coffee bean hopper is at, above or below the defined threshold value.

### BRIEF DESCRIPTION OF DRAWINGS

Preferred embodiments of the present invention will now be described, by way of examples only, with reference to the accompanying drawings:

FIG. 1 shows a perspective view of a filter cup according to a preferred embodiment of the invention.

FIG. 2 shows a perspective view of the filter cup of FIG. 1.

FIG. 3 shows a perspective view of a filter cup according to a second embodiment of the invention.

FIG. 4 shows a perspective view of a filter cup according to a third embodiment of the invention.

FIG. 5 shows a perspective view of the filter cup of FIG. 4.

FIG. 6 shows a perspective view of a portafilter used with the filter cup of FIG. 4.

FIG. 7 shows a perspective view of the portafilter of FIG. 6.

FIG. 8 shows a perspective view of the portafilter of FIG. 6.

FIG. 9 shows a perspective view of a filter cup according to a fourth embodiment of the invention.

FIG. 10 shows a perspective view of a filter cup according to a fifth embodiment of the invention mounted in a portafilter.

FIG. 11 shows a side view of an espresso machine used with the filter cups and portafilters of FIGS. 1 to 10.

FIG. 12A is a system block diagram of a grinder used with the espresso machine of FIG. 11.

FIG. 12B is a detailed view of a grinder used with the espresso machine of FIG. 11.

FIG. 13 shows a method according to a sixth embodiment of the invention.

FIG. 14 shows further details of the method of FIG. 13.

FIG. 15 shows further details of the method of FIG. 13

FIG. 16 shows further details of the method of FIG. 13

FIG. 17 shows further details of the method of FIG. 13

FIG. 18 shows a stand-alone grinder using the method of FIG. 13.

FIG. 19 shows an espresso machine with an integrated grinder using the method of FIG. 13.

FIG. 20 shows a PWM signal of an unloaded motor powering the grinder of FIGS. 12, 18, and 19.

FIG. 21 shows a PWM signal of a loaded motor powering the grinder of FIGS. 12, 18, and 19.

FIG. 22 shows a phase angle controlled motor signal of an unloaded motor powering the grinder of FIGS. 12, 18, and 19.

FIG. 23 shows a phase angle controlled motor signal of a loaded motor powering the grinder of FIGS. 12, 18, and 19.

FIG. 24 shows a method according to a seventh embodiment of the invention.

FIG. 25 shows further details of the method of FIG. 24.

FIGS. 26A and 26B schematically depict a technique for mounting the sensor to the espresso machine or the stand-alone grinder.

FIGS. 27 to 29 depict a magnet enclosure for securing the magnet to the filter cup.

### DESCRIPTION OF EMBODIMENTS

Where reference is made in any one or more of the accompanying drawings to steps and/or features, which have the same reference numerals or are separated by steps of 100, those steps and/or features have for the purposes of this description the same function(s) or operation(s), unless the contrary intention appears. For brevity, the set of references beginning at 100 and ending at 199 may be used to refer to all like features in other embodiments.

It is to be noted that the discussions contained in the “Background” section and that above relating to prior art arrangements relate to discussions of documents or devices which form public knowledge through their respective publication and/or use. Such should not be interpreted as a representation by the present inventor(s) or the patent applicant that such documents or devices in any way form part of the common general knowledge in the art.

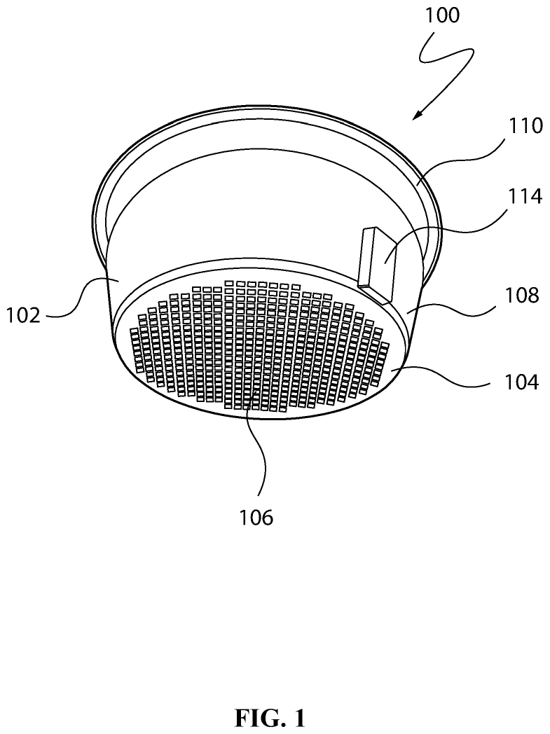

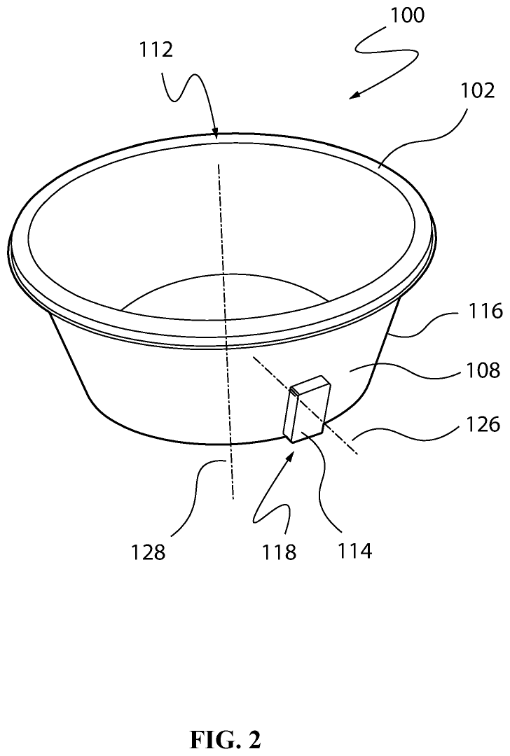

As seen in FIG. 1, a filter cup 100 for holding ground coffee according to a preferred embodiment of the invention includes a body 102 that has a floor 104 with a plurality of perforations 106. Preferably, the floor 104 is circular in shape and substantially the entire floor 104 is covered by the perforations 106. The body 102 further has a sidewall 108 extending upwardly from the floor 104 to a rim 110. As shown in FIG. 2, the rim 110, floor 104, and sidewall 108 define a cavity 112 for holding the ground coffee. Preferably, the cavity 112 is substantially rotationally symmetrical about a central axis 128.

The body 102 also has a boss portion 118, also referred to as a key, located on the sidewall 108 and extending outwardly therefrom. The boss portion 118 is adapted to engage, when the filter cup 100 is mounted on a portafilter, a corresponding portafilter key, such as a recess or slot, such that the filter cup 100 is mountable on the portafilter in a predetermined configuration. The body 102 further includes a magnet 114 for producing a magnetic field. In the embodiment shown in FIGS. 1 and 2, the magnet 114 is part of the boss portion 118 and thus attached to an outside surface 116 of the sidewall 108. The magnet 114 has a north and a south pole and produces a magnetic field along a magnet axis 126. In other embodiments, the magnet 114 does not engage the portafilter key.

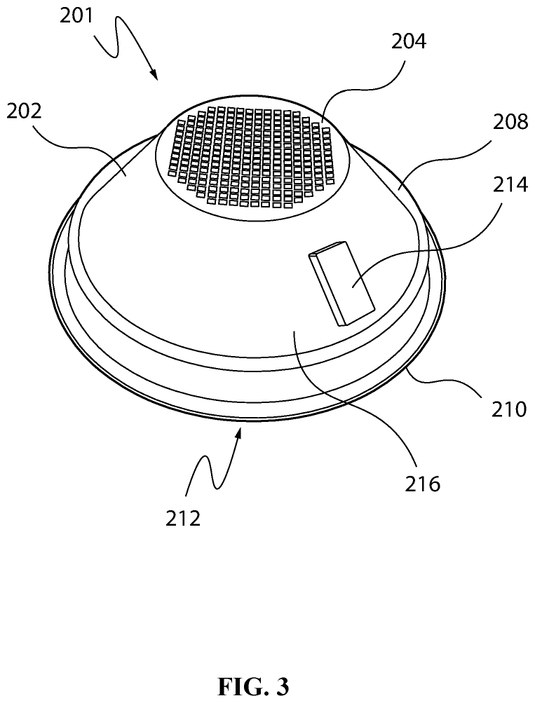

FIG. 3 shows a second embodiment of the filter cup 201. The filter cup 201 is substantially similar to filter cup 100 but dimensioned such that the rim 210, floor 204, and sidewall 208 define a cavity 212 that is smaller than the cavity 112. Preferably the cavity 112 is dimensioned to hold a volume of ground coffee corresponding to a double dose, while cavity 212 is preferably dimensioned to hold a volume of ground coffee corresponding to a single dose. The sidewall 208 of the filter cup 201 extends from the floor 204 at an angle and the magnet 214 is attached to the body 202 so as to be substantially parallel to the sidewall 208. Preferably, the magnet 214 is mounted to an outside surface 216 of the sidewall 208.

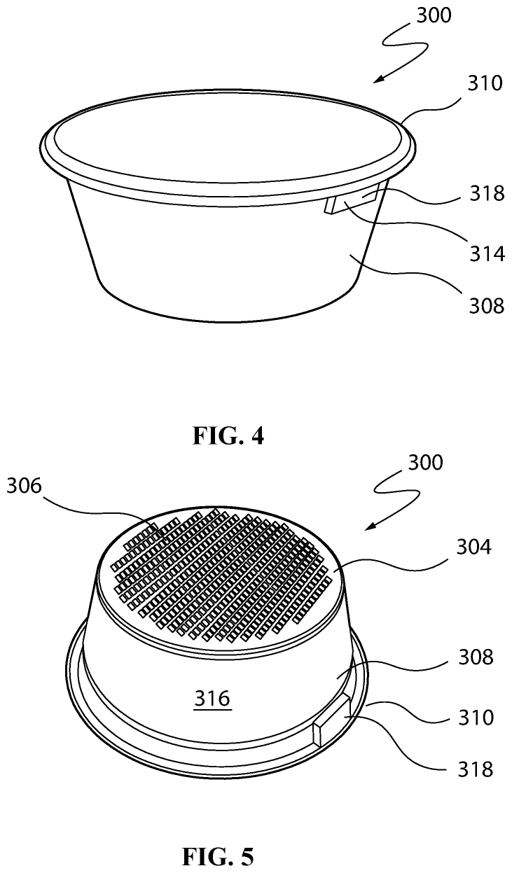

FIGS. 4 and 5 show a third embodiment of the filter cup 300. The filter cup 300 is substantially similar to filter cup 100 but the boss portion 318 (which, in some forms, includes the magnet 314), or the key, is located at an upper portion of the sidewall 308 adjacent the rim 310, such that it is adapted to engage, when the filter cup 300 is mounted on a portafilter, a corresponding portafilter key on the portafilter such that the filter cup is mountable on the portafilter in a predetermined configuration. In some embodiments, the boss portion 318 may be attached to the rim 310.

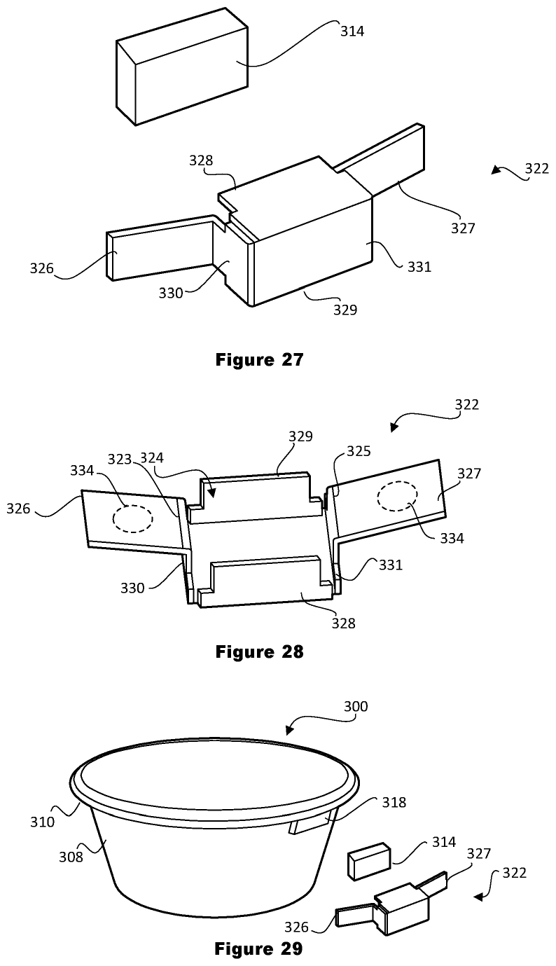

FIGS. 27 to 29 show one technique for attaching a magnet 314 to the boss portion 318. The magnet 314 is enclosed by a magnet enclosure 322 formed from sheet metal. The enclosure has opposing first and second sidewalls 328 and 329, and opposing third and fourth sidewalls 330 and 331, to define a retainment space 324 for the magnet 314. The sidewalls 328, 329, 330 and 331 are bent to extend generally perpendicular to the radially outward facing exterior surface of the boss 318. The sidewalls are dimensioned to create the retainment space 324 and the third and fourth sidewalls 330 and 331 connect to first and second flaps 326 and 327 at first and second gradient lines 323 and 325 respectively. The flaps attach to external surface of the filter cup sidewall 308. In some embodiments, the first and second flaps 326 and 327 are spot welded at locations 334 to the sidewall 308 to secure the magnet 314 in the retainment space 324 on the boss 318. In an alternative embodiment, the magnet 314 can be attached anywhere else on the outside surface of sidewall 308 (preferably closer to the top of the rim 310) of the filter cup 300 and secured by the magnet enclosure 322 without the boss portion 318.

The magnet enclosure 322 may be welded along a perimeter via MIG (Metal Inert Gas), SMAW (Shielded Metal Arc Welding), TIG (Tungsten Inert Gas), sub-arc, or other welding techniques. Furthermore, the magnet enclosure 322 can be secured by glue or silicone or any other bonding process.

In some forms of the magnet enclosure 322, the first and second flaps 326 and 327 are approximately 5 mm in length and 3.6 mm in width and 0.4 mm in thickness. The first, second, third and fourth side walls 308 to 331 are 5.6 mm wide and 3.6 mm high. The retainment space 324 is 7.4 mm wide and 5.4 mm high. The skilled worker will readily appreciate these dimensions are merely examples and may be varied as needed.

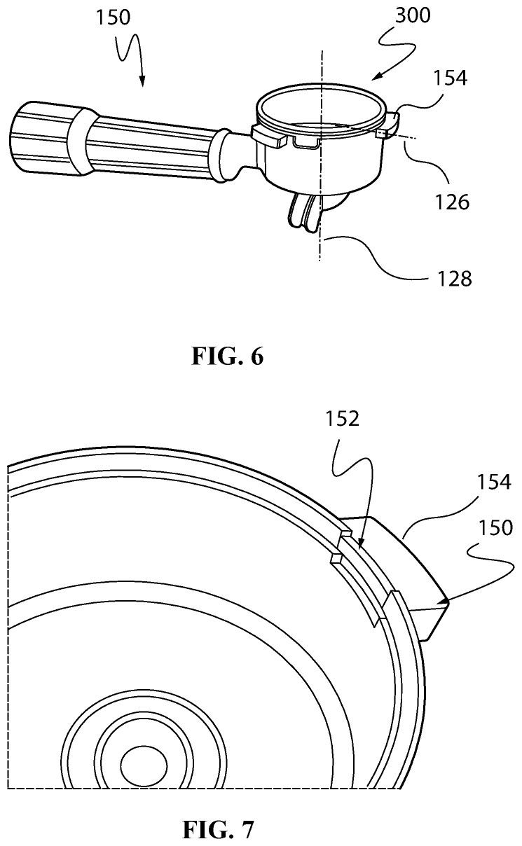

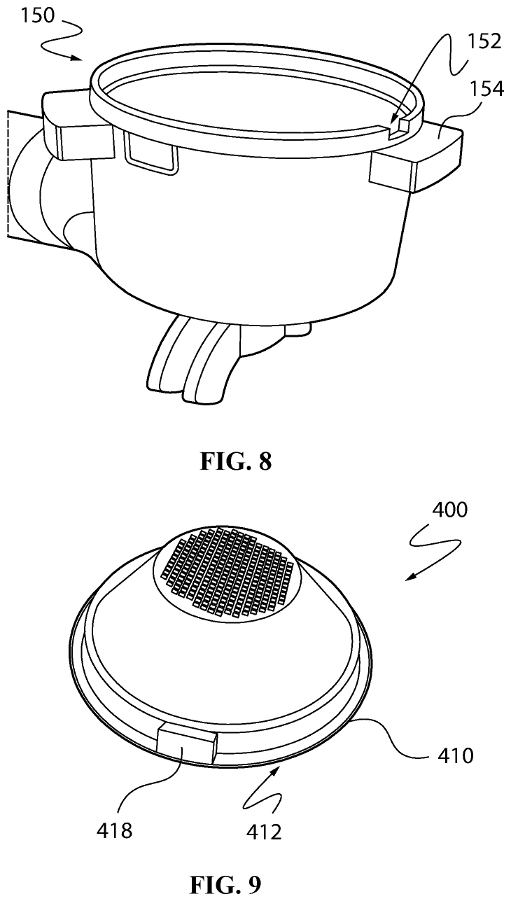

As seen in FIGS. 6 to 8, the filter cup 300 may be used with a portafilter 150. The portafilter 150 has a recess 152, also referred to as a portafilter key, for receiving the boss portion 318 such that the filter cup 300 is mountable on the portafilter 150 in a predetermined configuration, preferably such that the magnet axis 126 is in a predetermined direction relative to the portafilter 150. Preferably, the recess 152 is located on a rim 156 of the portafilter 150 to be engaged by the boss portion 318 located at the rim 310 of the filter cup 300.

FIG. 9 shows a fourth embodiment of the filter cup 400. The filter cup 400 is substantially similar to the filter cup 300, but the cavity 412 is sized substantially similarly to the cavity 212.

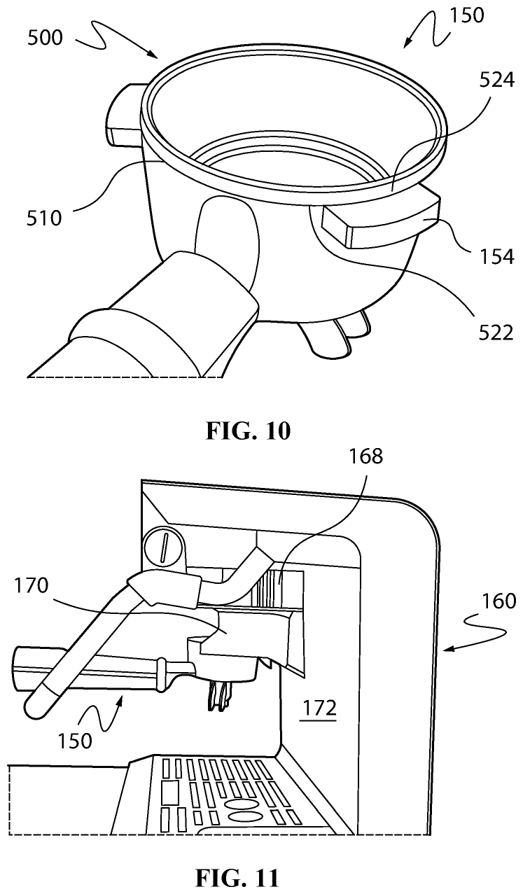

FIG. 10 shows a fifth embodiment of the filter cup 500. The filter cup 500 is substantially similar to the filter cup 100, but the key includes a flange portion 522 of the rim 510 that extends downwardly from the rim 510. Preferably, the filter cup 500 includes a plurality of flange portions 522, separated to leave a recess 524 between the flange portions 522. As shown in FIG. 10, the flange portions are adapted to engage a protrusion 154, also referred to as the portafilter key, on the portafilter 150 such that the filter cup 500 is mountable on the portafilter 150 in a predetermined configuration.

The body 102 of the filter cup 100 may have a plurality of magnets 114, located in similar locations, for example on the sidewall 108, but at regular or irregular intervals, or in different locations, for example on the sidewall 108, and on the floor 104.

The magnet 114 preferably has a predetermined property that influences the magnetic field produced by the magnet 114. The predetermined property includes preferably one or more of whether the north pole or the south pole face outwards from the filter cup 100, a direction of the magnet axis 126 relative to the central axis 128, a strength of the magnet 114, and a frequency of the magnetic field, if the magnet 114 is an electromagnet excited by an alternating current. Each combination of the predetermined property is preferably matched, in a predetermined look-up table (not shown), with a property of the filter cup 100. The property of the filter cup 100 includes preferably one or more of a volume of the cavity 112, a property of the floor 104, a property of the sidewall 108, and a manufacturer of the filter cup 100. Thus, when the magnetic field is measured and the predetermined property of the magnet 114 determined, the property of the filter cup 100 may be determined by referencing the look-up table.

Preferably, the portafilter 150 includes both the recess 152 and the protrusion 154, such that it may be used with filter cups 100 of various configurations. However the locations of the recess 152 and the protrusion 154 is independent from one another. In one embodiment, the portafilter 150 includes a sensor 172, preferably a magnetometer, (not shown) for determining a magnitude and/or direction of the magnetic field produced by the magnet 114. In some embodiments, the sensor 172 is a hall effect sensor. The sensor 172 is adapted to produce a magnet signal indicative of whether the north pole or the south pole face outwards from the filter cup 100, the magnitude, and/or the direction of the magnetic field. The portafilter 150 according to this embodiment also includes a portafilter processor (not shown) adapted to receive the magnet signal from the sensor 172 and determine a property of the filter cup based on the magnet signal. In one embodiment the portafilter processor may determine the predetermined property of the magnet 114 based on the magnitude and/or direction of the magnetic field and reference the look-up table (or via a set threshold or a set range of values) to determine the property of the filter cup. The portafilter processor is also adapted to produce a filter cup signal indicative of the property of the filter cup

The portafilter 150 may further includes a communication module (not shown) adapted to receive the filter cup signal from the portafilter processor and transmit the filter cup signal to a receiver module located away from the portafilter 150.

Referring now to FIG. 11, the present disclosure also relates to an espresso machine 160 used with the portafilter 150 holding the filter cup 100. The espresso machine 160 may include a grinder fitting 170 for holding the portafilter 150 whilst a grinder (not shown) is operated to deposit ground coffee into the filter cup 100. The espresso machine 160 may also include an extraction fitting 168 for holding the portafilter while coffee beverage is extracted from the coffee grounds.

In a first embodiment, the espresso machine 160 includes the receiver module to receive the filter cup signal from the communication module in the portafilter 150. The espresso machine 160 further includes a machine processor (not shown) adapted to receive the filter cup signal from the receiver module and modify one or more machine parameter of the espresso machine 160 based on the filter cup signal. The machine parameter includes one or more of an operability of the espresso machine 160 (i.e. the espresso machine may be disabled based on an incorrect or non-existent filter cup signal), a ground coffee quantity (preferably an amount of time for which the grinder of the espresso machine 160 is operated), a brewing pressure setting or profile, a pre-infusion period, a water quantity, and a water flow rate.

In another embodiment, the espresso machine 160 may include the sensor 172, preferably a magnetometer or a hall effect sensor, as specified above and the machine processor is adapted to receive the magnet signal from the sensor and determine the property of the filter cup based on the magnet signal. The machine processor may then modify one or more machine parameter based on the property of the filter cup. The sensor 172 is preferably located in the espresso machine 160 such that, when the portafilter 150 with the filter cup 100 is held in the grinder fitting 170, the sensor 172 is able to determine the magnitude and/or direction of the magnetic field produced by the magnet 114. Alternatively or in addition, the sensor 172 may also be located in the espresso machine 160 such that, when the portafilter 150 with the filter cup 100 is held in the extraction fitting, the sensor is able to determine the magnitude and/or direction of the magnetic field produced by the magnet 114.

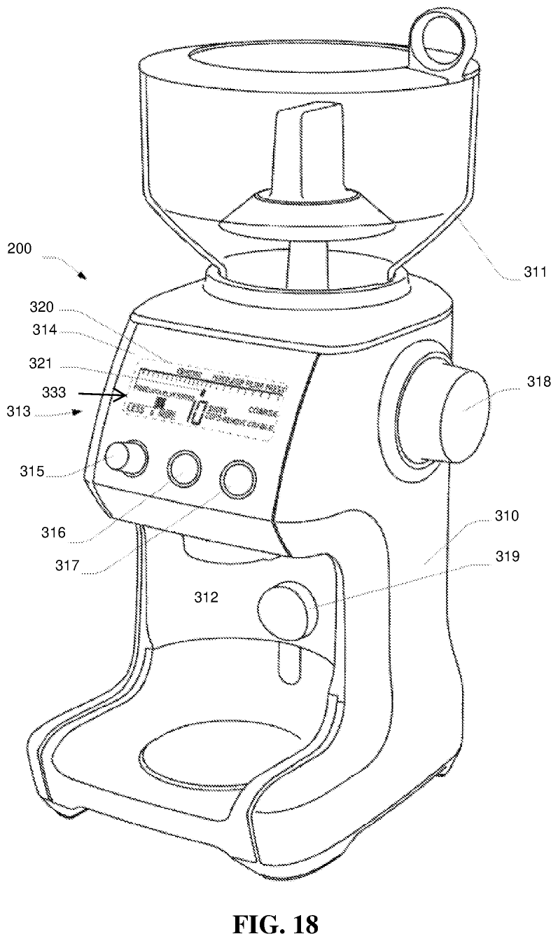

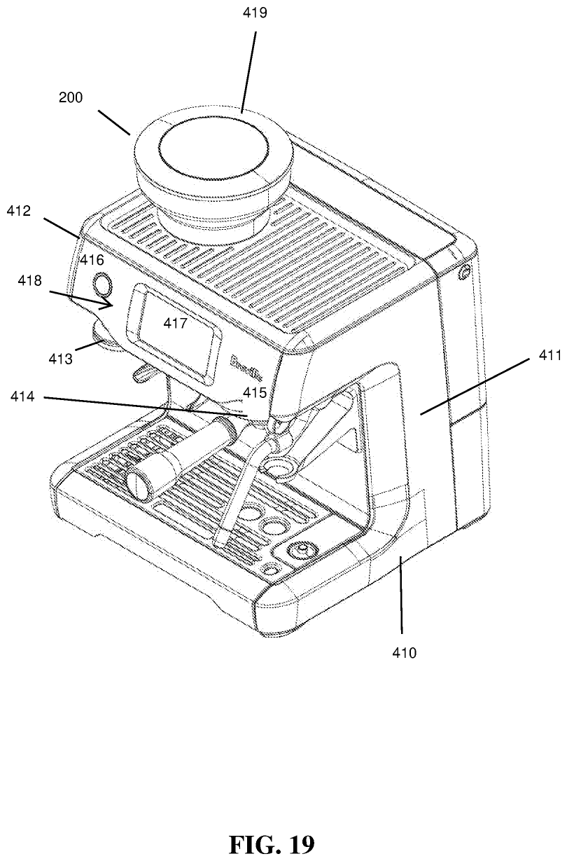

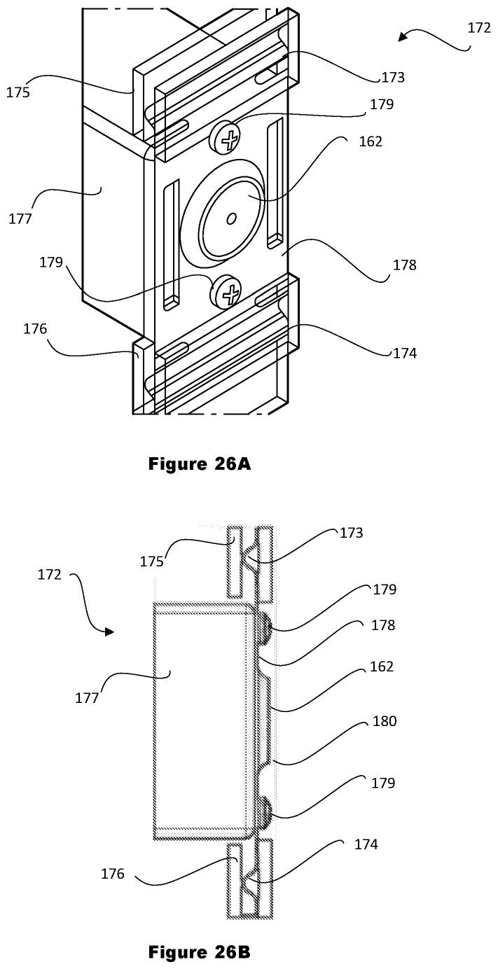

FIGS. 26A and 26B schematically show a suitable technique for mounting the sensor 172 in the stand-alone grinder 200 (see FIG. 18) or the espresso machine 160 (see FIG. 19). The portafilter 150 is configured to engage the discharge area 312 of the stand-alone grinder 200, or the grinder fitting 170 of the built-in grinder 170, or extraction fitting of the espresso machine 160. The sensor 172 can be fitted to sense the magnet 114 at any or all of these locations. In each of these options, the relative position of magnet 114 and the sensor 172 should be closely controlled. Minor misalignments cause variation in the magnetic field at the sensor 172. In turn, this inaccuracy can result in the processor assigning an incorrect portafilter size and/or coffee dose.

The sensor 172 is enclosed within a housing 177 fixed to spring plate 178 with suitable fasteners 179. The ends of the spring plate 178 and held in a top and bottom channel (175 and 176) to mount the housing 177 in a recess of the grinder 200 or espresso machine 160. The spring plate 178 is structured to bow outwards from the recess such that the housing 177 has some relative movement within the recess. Similarly, at least one end of the spring plate 178 should not be fixed within the relatively wide (approx. 0.5 mm-2.5 mm wide) channels 175 or 176 to allow a small amount of sliding movement. The spring plate 178 has a raised engagement face 162 that is urged into abutting engagement the portafilter as the user engaging it in the stand-alone grinder 200 or the espresso machine 160. The spring plate 178 presses the engagement face 162 onto the portafilter for a consistent spacing between the sensor 172 and the magnet 114. The more consistent positioning of the sensor 172 relative to the magnet 114 improves sensor accuracy.

The relatively wide channels 175 and 176 provides tolerance to accommodate some coffee powder ingress without detrimental effect to the operation of the sprung mounting system. Likewise, the spring plate 178 can incorporate apertures to tailor the bending stiffness to a suitable outward bias on the engagement face 162. Similarly, the raised engagement face 162 can configure its peripheral shape 180 for smoother contacting engagement with the exterior of the portafilter.

In any embodiment, the espresso machine 160 may include a memory module (not shown) in communication with the machine processor and containing a database of predetermined coffee extraction profiles, each extraction profile being associated with a predetermined set of filter cup properties. For example, a particular extraction profile may be associated with a double-shot-sized cavity 112 and a single wall sidewall 108. Each extraction profile contains information relating to one or more of the machine parameters. The machine processor may be adapted to access the database and modify the machine parameters of the espresso machine 160 to coincide with a particular extraction profile that corresponds to a particular filter cup property or set of filter cup properties determined by measuring the magnetic field produced by the magnet 114.

In another embodiment, the espresso machine 160 may include a user interface (not shown) in communication with the machine processor. The machine processor may be adapted to modify the extraction profile stored in the database based on a user input received at the user interface.

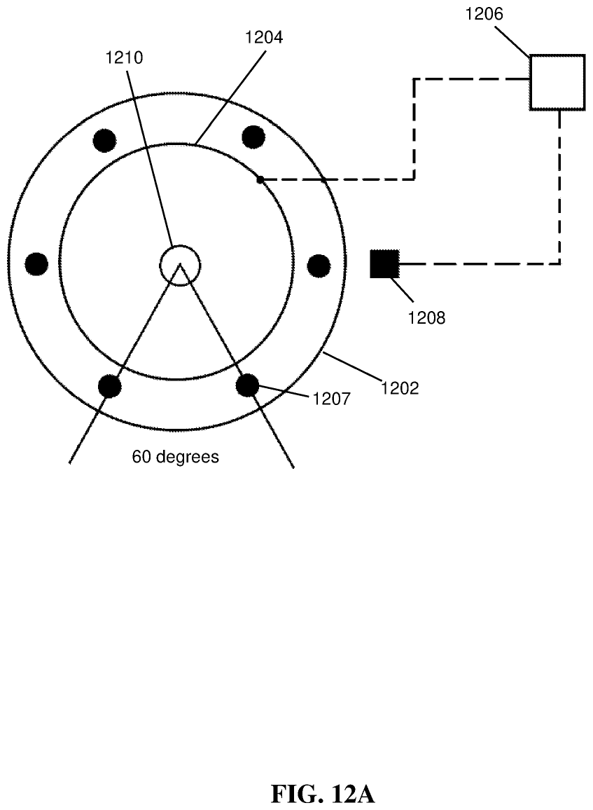

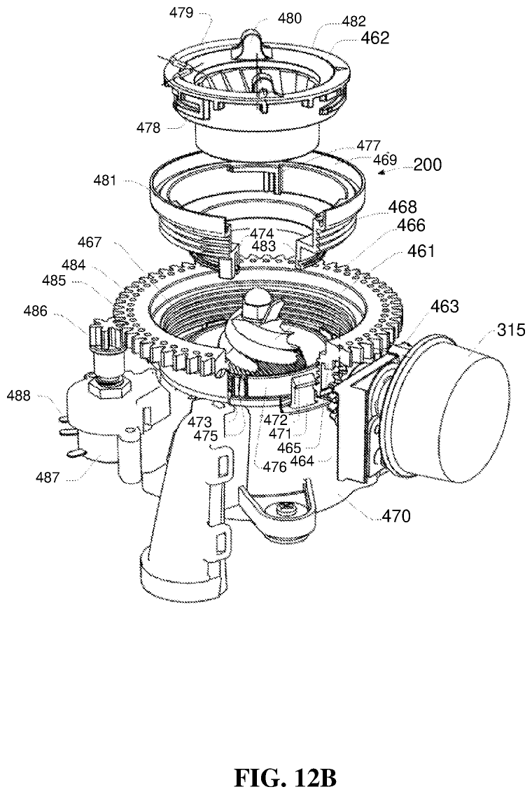

FIG. 12A shows a system block diagram of a grinder used with the espresso machine of FIG. 11. The grinding element (auger) 1202 is shown in a top view and has, in this example, six motor shaft position sensors 1207 in the form of magnetic poles. That is, when the motor shaft 1210 rotates under control of the motor 1204 (which is controlled by the controller 1206), the magnet with the magnetic poles 1207 rotates with the grinding element 1202. In this example, there are six magnetic poles that are alternate north/south poles, thus having three north poles and three south poles positioned alternately. These magnetic poles are positioned equidistantly around the circumference of the magnet, and so are separated by a 60 degree angle relative to the motor shaft 1210. A magnetic sensor 1208 is positioned close to the rotating grinding element 1202 to detect when each of the magnetic poles 1207 passes the magnetic sensor 1208. The position signals from the magnetic sensor 1208 and communicated back to the controller 1206. Therefore, the magnetic sensor 1208 (which detects the position of the grinding element 1202) provides one or more position signals to the controller, the position signals being indicative of a position of the grinding element as the grinding element is driven by the motor.

It will be understood that, as an alternative, separate magnets may be used rather than a single magnetic block. Further, it will be understood that any number of suitable magnetic poles may be used, other than six. Further, it will be understood that a ring with equidistant holes may also be used as an alternative, where infra-red LEDs and sensors may be arranged to detect when the infra-red light passes through the holes during rotation of the ring and the grinding element.

FIG. 12B shows a sixth embodiment of the present invention providing an espresso machine 160 with a grinder 200 for manufacturing ground coffee from coffee beans. This grinder is described in more detail below, but is initially introduced here in the broad terms used in FIG. 12A. The grinder 200 has a grinding element 1202, such as a grinder head of a burr grinder, for grinding coffee beans to ground coffee. The grinder 200 further has a motor 1204 operable to drive the grinding element 1202, and a controller 1206. The functions described herein as being performed by the controller 1206 may be carried out instead, or in addition, by the machine processor 164. The controller 1206 is adapted to control operation of the motor 1204, for example by including a motor controller (not shown).

The grinder 200 further includes a grinder position sensor 1208 for providing a position signal to the controller 1206. The position signal is indicative of a position of the grinding element 1202, for example a rotational position of the grinding element 1202, as the grinding element 1202 is driven by the motor 1204. The controller 1206 is adapted to operate the motor 1204 based on the position signal. The grinder position sensor 1208 may include a motor shaft position sensor 1208 for determining a position, for example a rotational position, of a motor shaft 1210 of the motor 1204. However, the methods described herein work equally based on an unconverted position signal based on the position of the motor shaft 1210, as relevant ratios would be maintained.

In one example, the grinder position sensor is adapted to detect at least 1 rotary position of the motor. In the embodiment shown in FIGS. 12A and 12B, the grinder position sensor 1208 is adapted to detect six, preferably discrete, and preferably equally distributed rotary positions of the motor shaft 1210. In other embodiments, the grinder position sensor 1208 may include a hall effect sensor, where in this embodiment, the motor shaft 1210 may include one or more magnets (not shown), preferably at least six magnets, more preferably a ring magnet with six poles, spaced about a motor shaft axis 1212 to interact with the Hall effect sensor when adjacent the hall effect sensor. In some embodiments, the position signal is thus indicative of a discrete position of the grinding element 1202, selected from a plurality of discrete positions. In other embodiments, the position signal includes a square wave having a signal width, the signal width being related to the time taken by the magnet, or pole of the magnet, traversing the grinder position sensor 1208. For example, six discrete positions of the grinding element 1202 may be equally distributed in 60° increments about centroid of the movement of the grinding element 1202 and the position signal is indicative of which of the 6 discrete positions the grinding element 1202 is in, or was last measured in. The signal width is also indicative of a speed of the motor shaft 1210 relative to the grinder position sensor 1208.

In preferred embodiment, the grinder 200 further includes a motor current sensor (not shown) for providing a motor current signal to the controller 1206. The motor current sensor may be integrated with the controller 1206, the motor controller, or a standalone component. The motor current signal is indicative of a current drawn by the motor 1204. The controller 1206 may be adapted to, alternatively or in addition to the position signal, operate the motor 1204 based on the motor current signal.

The following describes a grinder or method for manufacturing ground coffee from coffee beans and determining whether a coffee bean level in the coffee bean hopper is at, above or below a defined threshold value. That is, the determination of the coffee bean level may be a determination that the coffee bean hopper is empty, near empty or the level of the beans has dropped below a desired level (for example, that the level is less than half full).

For example, the threshold value may be 0% full, 5% full, 10% full, 15% full, 20% full, 25% full, or any other suitable value thereabouts. The determination of the coffee bean level may be that the level is at a defined percentage of fullness, e.g. 0%, 5%, 10%, 15%, 20%, 25%, or any other suitable value thereabouts. The determination of the coffee bean level may be that the level is below a defined percentage of fullness, e.g. below 25%, below 20%, below 15%, below 10%, below 5%, or any other suitable value thereabouts.

As another example, the threshold value may be 100% empty, 95% empty, 90% empty, 85% empty, 80% empty, 75% empty, or any other suitable value thereabouts. The determination of the coffee bean level may be that the level is at a defined percentage of emptiness, e.g. 100%, 95%, 90%, 85%, 80%, 75%, or any other suitable value thereabouts. The determination of the coffee bean level may be that the level is above a defined percentage of emptiness, e.g. above 95%, above 90%, above 85%, above 80%, above 75%, or any other suitable value thereabouts.

The grinder may be a stand-alone grinder or a grinder that is incorporated, or part of, an espresso machine.

FIG. 18 shows an example of a stand-alone grinder 200. As shown in FIG. 18, an electrical, motorised coffee grinder 200 comprises a base 310 and its hopper 311. The base 310 has a recess or discharge area 312 into which ground coffee is dispensed. The discharge area can accommodate containers such as a portafilter, filter or storage canister. The base 310 has a head 313 located above the recess 312. A front panel or surface 314 of the head 313 features various user controls including (as will be further explained) a discharge amount adjustment rotating knob 315, a push button or other user control for choosing discreet preset discharge amounts 316, a start/cancel button 317 and a grind size selector dial 318. The grind size selector dial 318 mechanically controls the vertical movement of an upper burr of the grinder 200. The spacing between the upper burr and a lower burr determines the grind size. The front panel 314 also features an electronic display 320. The dial 318 also controls the appearance of the display 320 by causing one of a number of arrow icons to appear in the appropriate position under a grind size index line 321 (see FIG. 18). The preset amount button 316 allows the user to choose an amount of coffee grinds to discharge. Depressing this button causes the display 320 to change between numeric values in discrete increments. Each displayed numeric value represents a grinding time for each grind type. Grinding time and grinding type are related to the discharge amount in accordance with a look up table. A rear surface of the recess 312 also has an external button 319 coupled to an electrical switch that is activated with the presence of the portafilter 150.

FIG. 19 shows an example of an espresso machine with a grinder 200. As shown in FIG. 19, an espresso machine with built-in coffee grinder comprises a base 410 that supports a carriage within which is contained a drip tray with cover and a concealed storage tray. An upright portion 411 extends from the base 410 and supports a ledge 412. The underside of the ledge features a removable tamper 413, a portafilter support cradle 414, such as the extraction fitting 168 (see FIG. 11), that is located below an internal coffee grinder and the group head or brew head 415. The front face of the ledge comprises various user controls 416, a pressure gauge 417 and various indicators 418. A removable bean hopper 419 discharges beans into the internal grinder. The controller 1206 (see FIG. 12A) receives the various user inputs and operational parameters produced by the machine's internal sensors and using these, controls the operation of the grinder 200, indicators and the machine's boiler, hot water and steam systems.

Returning to FIG. 12B, the grinder 200 also comprises a motor driven lower burr 461 and an upper burr 462. In this example, the manual grind size adjustment knob 418 rotates. The gearbox 463 in turn rotates a drive gear 464 that acts on teeth 465 formed around the main opening of the main or driven gear 466. The driven gear 466 has an internal bore with fine threads 467 that engage and cooperate with fine threads 468 located on the outside surface of the upper burr holder or carriage 469. The rotating knob 418 is able to affect very fine rotational control over the driven gear 466. The driven gear is retained for rotational movement on the grinder housing 470 by a two or (preferably three) tabs 471 that are integral with the housing 470. Each tab has a tooth 472 that engages a rim 473 that is circumferential and internal to the driven gear 466. Thus, the driven gear 466 can rotate but not translate axially. However, the upper burr carriage 469 is restrained from rotation and thus translates either up or down according to the rotation of the driven gear 466. The carriage 469 has, in this example, a pair of vertically oriented jaws 474 that engage a web section 475 formed on a pilot rim that is part of the grinder housing and that surrounds the lower burr 461. The upper burr carriage 469 and the upper burr 462 are removably interconnected by male and female bayonet elements 477, 478 that allow the upper burr 462 to be rotated a fraction of a turn e.g. one third of a turn and thereby removed from or reinserted into the carriage 469. A generally “U” shaped handle 479 cooperates with a pair of ears 480 that protrude from an upper surface of the upper burr 462. Thus, regardless of the position that the upper burr carriage 469 is in, the upper burr 462 itself can be easily removed and reinserted without altering its spacing from the lower burr 461. The carriage 469 further comprises an upper vertically oriented rim 481 for receiving the top flange 482 of the upper burr. The carriage 469 also comprises an intermediate portion with exterior fine threads 468 and a lower section of reduced diameter 483 that includes the jaws 474 and a lower pilot rim for engaging the grinder housing.

The main or driven gear 466 further comprises an external gear ring 484 with radially oriented gear teeth 485. The continuous ring formed by the teeth 485 engages with a pinion gear 486 that drives a ten turn potentiometer 487. The potentiometer outputs 488 are monitored by the grinder's controller 206 and the degree of rotation of the pinion gear 486 is translated into a visual indication on the display 320 that is indicative of the grind size and therefore directly indicative of the vertical separation between the lower burr 461 and the upper burr 462. The pinion 486 could also be attached to other forms of monitoring the extent of rotation of the main gear 466, including a gear mechanism for providing an analogue indication of the grind size.

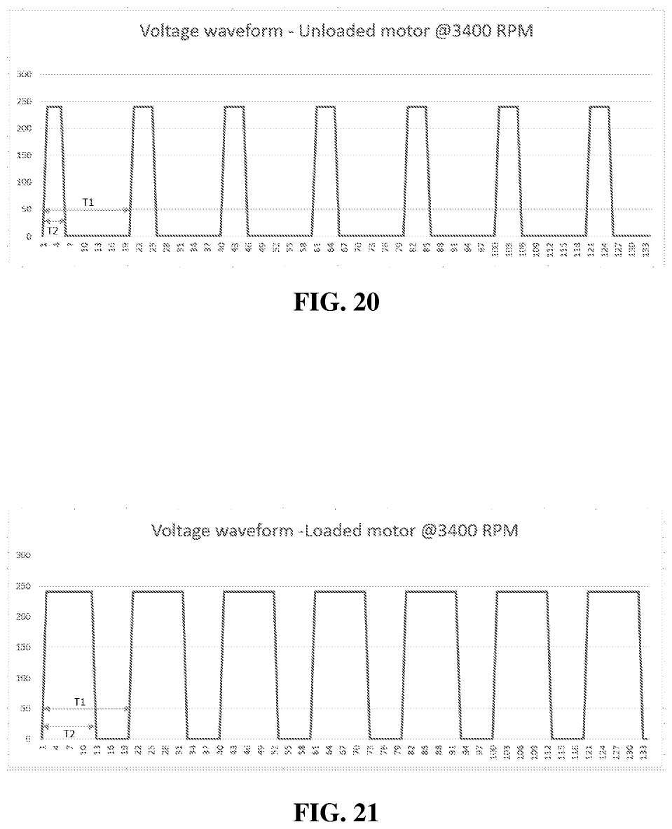

The motor in either of the stand-alone grinder or the grinder in the espresso machine may be controlled using a power control signal that is generated using the pulse width modulation (PWM) control technique, where pulse width modulation (PWM) duty cycle value is adjusted to control the amount of power being applied to the motor. FIGS. 20 and 21 show example voltage waveforms of an unloaded and loaded motor using the PWM control method. T1 is the PWM frequency, which is a constant number. T2 is the time in which the full voltage is provided to the motor. Varying the T2 value regulates the average voltage (or power) being applied to the motor. The ratio of T2/T1 is the duty cycle which provides an indication of the voltage (e.g. 25% of the full voltage) supply to the motor. By using PID control algorithms, the micro controller unit (MCU) or controller measures the real time motor speed and calculates the necessary voltage to maintain a predetermined speed.

If the motor load is less, then a smaller duty cycle is required, whereas if the motor load is high, a higher duty cycle is required. By monitoring the duty cycle, the controller can determine the motor load status.

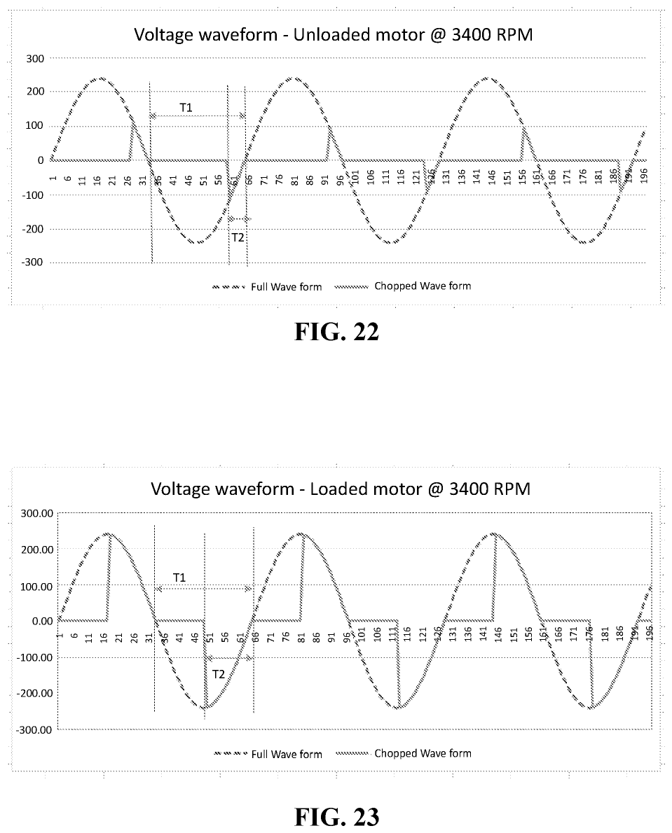

Alternatively, the motor in either of the stand-alone grinder or the grinder in the espresso machine may be controlled using a power control signal that is generated using the phase angle control method, where the ON period for each sine wave is adjusted using a triac in the power control system to control the amount of power being applied to the motor. FIGS. 22 and 23 show example voltage waveforms of an unloaded and loaded motor being controlled using the phase angle control method.

In the phase angle control method, the controller controls the ON period of each sine wave using an appropriate device such as, for example, a triac. In the figures, different timings for the switching ON period provide different voltages to the motor. Similarly, with PID control methods, based on the speed measurements the controller may be arranged to calculate the required voltage for the motor to maintain a predetermined speed by varying the T2 time. The T1 time is a constant for a given AC voltage, for example T1 may be 10 ms for a 50 Hz AC voltage.

The phase angle is defined as T2/T1, as a % of total time, and indicates the voltage supplied to the motor.

In the graphs shown, it can be seen that when motors run unloaded, T2 is smaller. This indicates that the power, being one or both of voltage and current, required to maintain that particular speed is lower. Whereas, when the loaded motor runs, it requires a higher power to maintain the speed.

In the coffee grinder 200, whether as a stand-alone coffee grinder or as a coffee grinder integrated into a coffee machine (e.g. an espresso machine), when the coffee bean hopper is empty, the load on the motor is at a minimum due to the grinding element not being required to grind any coffee beans. Therefore, the motor requires a relatively low power, being one or both of voltage and current, to maintain the correct (e.g. set speed). It is therefore possible to detect how empty (or full) a coffee bean hopper is by monitoring the PWM duty cycle of a DC system or the phase angle of an AC system, as explained on more detail herein.

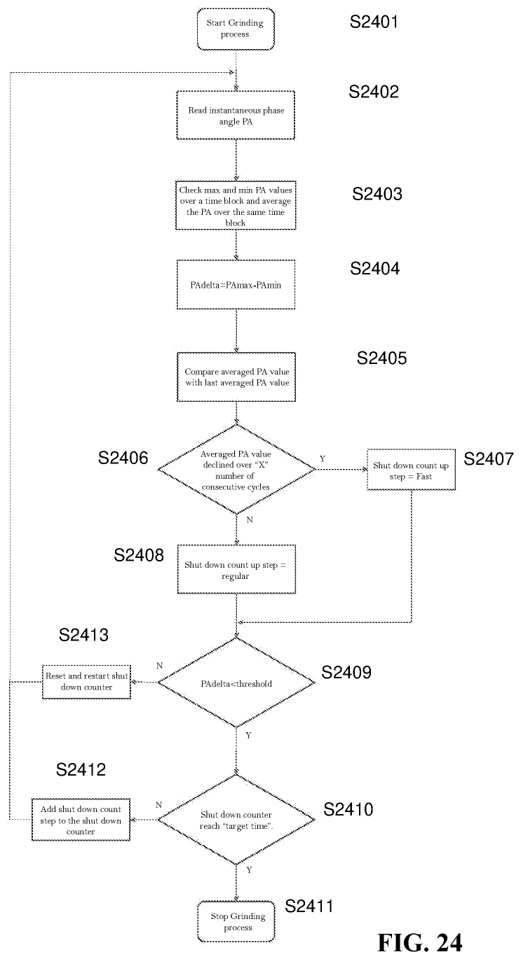

According to an example shown in FIG. 24, the following processes may be executed.

At step S2401, the grinding process starts by operating the grinder 200 at the initial control set point. At step S2402, an instantaneous phase angle PA is determined. This is described in more detail herein. Further, it will be understood that, as alternatives, the system may determine an instantaneous PWM duty cycle.

At step S2403, the max and min PA values are monitored or checked over a time block period and the PA is averaged over the same time block period. The time block period may be any suitable time block period as determined by test results. Further, different coarseness setting may be monitored by the controller to adjust or change the time block period used in order to expedite the shut-down process.

At step S2404, the controller calculates PAdelta=PAmax−PAmin.

At step S2405, the controller compares the averaged PA value with the previous averaged PA value.

At step S2406, the controller determines whether the averaged PA value has reduced or declined over “X” number of consecutive cycles.

If at step S2406 the controller determines that the averaged PA value has reduced, a shutdown count up step is set to “fast” at step S2407.

If at step S2406 the controller determines that the averaged PA value has not reduced (or has increased), the shut-down count up step is set to “regular” at step S2408.

At step S2409, the controller determines whether PAdelta less than a threshold value. The threshold value may be set to a different value dependent on the different coarseness settings that could be used. This may assist in increasing response times.

If at step S2409, the controller determines that PAdelta is less than the threshold value, the controller then, at step S2410, determines whether the shut-down counter has reached a predetermined target time. The target time may be set based on suitable test results. For example, the target time may be set as ˜3-4 time blocks. If at step S2410 the controller determines that the shut-down counter has reached the target time, at step S2411, the grinding process is stopped. Whereas, if at step S2410, the controller determines that the shut-down counter has not reached the target time, at step S2412, the controller adds a shut-down count step to the shut-down counter. If at step S2409, the controller determines that PAdelta is not less than the threshold value, the controller then, at step S2413, resets and restarts the shut-down counter.

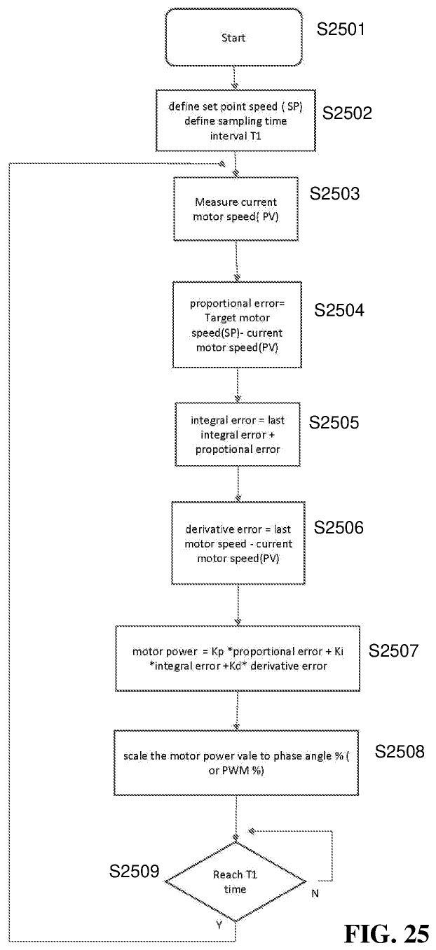

The following process, shown in FIG. 25, shows how the instantaneous phase angle PA is determined in step S2402.

At step S2501, the process starts.

At step S2502, the controller defines a set point speed (SP) and defines a sampling time interval T1.

At step S2503, the controller measures the current motor speed (PV).

At step S2504, the controller determines the proportional error based on Target motor speed (SP)−current motor speed (PV).

At step S2505, the controller determines the integral error based on the previous integral error+the proportional error.

At step S2506, the controller determines the derivative error based on the previous motor speed−the current motor speed (PV).

At step S2507, the controller determines the motor power based on Kp*proportional error+Ki*integral error+Kd*derivative error. Kp, Ki and Kd are constants that are selected based on test data collected by the system.

At step S2508, the controller scales the motor power vale to a phase angle percentage value. Alternatively, if the pulse width duty cycle value is being used, the controller scales the motor power vale to a pulse width duty cycle percentage value.

At step S2509, the controller determines whether T1 time has been reached. If T1 has not been reached the process stays in this loop monitoring T1. If T1 is reached, the process returns to step S2503 to measure the current motor speed (PV).

The proportional term considers how far Process Variable (PV) is from setpoint (SP) at any instant in time. Its contribution to the control set point is based on the size of an error value e(t) only at time t. As e(t) grows or shrinks, the influence of the proportional term grows or shrinks immediately and proportionately.

The integral term addresses how long and how far PV has been away from SP. The integral term is continually summing e(t). Thus, even a small error, if it persists, will have a sum total that grows over time and the influence of the integral term will similarly grow.

A derivative describes how steep a curve is. More properly, a derivative describes the slope or the rate of change of a signal trace at a particular point in time. Accordingly, the derivative term in the PID equation above considers how fast or the rate at which, error (or PV) is changing at the current moment.

Therefore, there is provided a grinder that is suitable for manufacturing ground coffee from coffee beans. The grinder may have a grinding element that is suitable for grinding the coffee beans to ground coffee. For example, the grinder may operate based on a desired (set) coarseness value. The motor in the grinder is operable to drive the grinding element in order to grind the beans. A coffee bean hopper enables a user to place coffee beans therein so the beans may be provided to the grinding element for grinding.

The controller of the grinder is arranged or adapted to control operation of the motor based on control signals generated by the controller in response to the processes being run and monitored. The controller is arranged to monitor a speed of the motor to determine a power control signal being applied to the motor. The speed of the motor may be monitored using any suitable techniques, such as monitoring the axial rotation of the shaft of the motor. For example, the shaft of the motor may have a magnetic element attached thereto or incorporated therein. The shaft may operate with a hall effect sensor arranged in close proximity to detect the rotation of the shaft such that the controller can determine the speed of the motor.

The controller may then determine whether a coffee bean level in the coffee bean hopper is above or below a defined threshold value based on the determined power control signal being above or below a defined threshold, for example, over a determined period of time. For example, the power control signal may be a pulse width modulation (PWM) duty cycle value or a phase angle value as described herein.

The power control signal may be a pulse width modulation (PWM) duty cycle percentage value based on a motor power value determined by the controller as described herein.

The power control signal may be a phase angle percentage value based on a motor power value determined by the controller as described herein.

The power control signal may be determined by the controller by applying a proportion integral derivative (PID) calculation to the speed of the motor as described herein.

The controller may be arranged to monitor a voltage being applied to the motor and then adjust (e.g. increase or decrease) the defined threshold value based on the monitored voltage as well as the determined power control signal.

The controller may be arranged to shut down the grinder upon determining that the coffee bean level in the coffee bean hopper is at, above or below the defined threshold value, by determining that the power control signal is at, above or below the defined threshold value, for example, over a determined period of time.

Therefore, the process includes the following steps that are suitable for manufacturing ground coffee from coffee beans in a grinder. The process includes the step of grinding coffee beans to ground coffee using a motor operable to drive a grinding element. Further, the process includes the step of providing coffee beans to the grinding element via a coffee bean hopper. Further, the process includes the step of controlling operation of the motor. Further, the process includes the step of monitoring a speed of the motor to determine a power control signal being applied to the motor. Further, the process includes the step of determining whether a coffee bean level in the coffee bean hopper is above or below a defined threshold value based on the determined power control signal, for example, over a determined period of time.

Further, the process may include the step of monitoring a voltage being applied to the motor and adjusting the defined threshold value based on the monitored voltage.

Further, the process includes the step of shutting down the grinder upon determining that the coffee bean level in the coffee bean hopper is at, above or below the defined threshold value.

One advantage of the process described is that the determinations of how empty or full a coffee bean hopper is are made using relative data rather than absolute data, and so assist in minimizing errors in the system brought about by, for example, component tolerances, different power ratings etc.

Use of the filter cup 100 will now be discussed.

A user may select a filter cup 100 having filter cup properties desirable for the type of coffee beverage, or type of coffee beans or ground coffee to be extracted, the user wishes to consume. The filter cup 100 is mounted on the portafilter 150 such that the key, being the boss portion 118 or flange portion 522, engages the portafilter key, being the recess 152 or protrusion 154, respectively. The filter cup 100 is now mounted on the portafilter 150 in the predetermined orientation. The portafilter 150 is inserted into the grinder fitting 170. The sensor 172 determines the magnitude and/or direction of the magnetic field and produces the magnet signal.

In the embodiment including the portafilter processor, the portafilter processor receives the magnet signal, determines the property of the filter cup 100 based on the magnet signal for example by referring to the predetermined look-up table, produces the filter cup signal, and sends the filter cup signal, using the communication module, to the receiver module. The machine processor then receives the filter cup signal from the receiver module and modifies one or more of the machine parameters based on the filter cup signal.

In the embodiment not including the portafilter processor, the machine processor receives the magnet signal, determines the property of the filter cup 100 for example by referring to the predetermined look-up table, and modifies one or more of the machine parameters based on the property of the filter cup 100.

In either scenario, the machine processor may access the database of predetermined extraction profiles to obtain the required machine parameters. The user may modify the extraction profile associated with the determined property of the filter cup 100 by providing the relevant user input at the user interface.

The user then activates the grinder, which is operated for an amount of time to produce the ground coffee quantity, in another embodiment, the grinder is operated until a load cell (not shown) being acted on by the portafilter 150 determines that a predetermined threshold weight has been reached. The user then removes the portafilter 150 from the grinder fitting 170 and places the portafilter 150 into the extraction fitting 168. The user then activates an extraction cycle. A pump and/or heater of the espresso machine 160 are operated to produce a brewing pressure profile which may include a pre-infusion period of a lowered brewing pressure. The pump and/or heater are also operated to extract the coffee beverage using the water quantity and/or the water flow rate set by the machine processor.

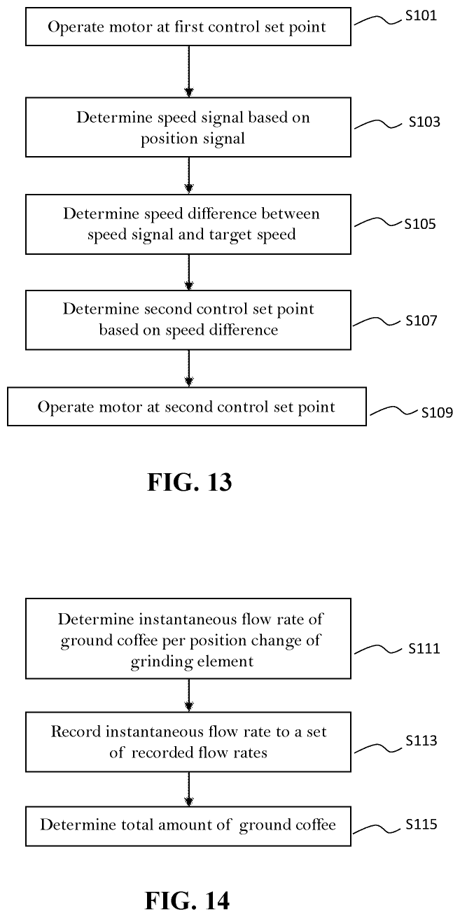

Turning to the embodiment of FIGS. 12A and 12B, and as shown in FIGS. 13 to 17, a method 250 of manufacturing ground coffee using the grinder 200 according to a preferred embodiment of the invention commences, after a user having requested ground coffee at the user interface 166, or the machine processor 164 determining that ground coffee is required, at step S101 operating, using the processor 206, the motor 204 at a first control set point to drive the grinding element 202. A motor turn counter is initiated at zero and incremented each time the grinder position sensor 208 indicates that the motor shaft 210 has moved by an increment. A target motor turn count is set by the controller 206, based on, for example, the desired grind amount, and the desired grind size. At step S103, the controller 206 determines a speed signal based on the position signal provided by the grinder position sensor 208, for example by performing discrete differentiation over a time series of the position signal. In another embodiment, the speed signal is based on the signal width of the position signal square wave, the signal width being directly indicative of a speed of the motor shaft 210. The speed signal is thus indicative of an instantaneous speed of the grinding element 202. If the grinder position sensor 208 includes the motor shaft position sensor, the speed signal is, firstly, indicative of an instantaneous speed of the motor shaft 210. Alternatively, subsequent calculations may be performed using the instantaneous speed of the motor shaft 210 directly.

At step S105, the controller 206 determines a speed difference between the speed signal and a predetermined target speed, for example 3200 rpm. At step S107 the controller 206 determines a second control set point based on the speed difference. For example, the second control set point may be selected such that the speed signal will likely be closer to the predetermined target speed. The selection of the second control set point may be performed using PID control. Alternatively or in addition, the selection of the second control set point may be performed using a predetermined function of the signal width of the position signal square wave. At step S109, the processor 206 operates the motor 204 at the second motor speed.

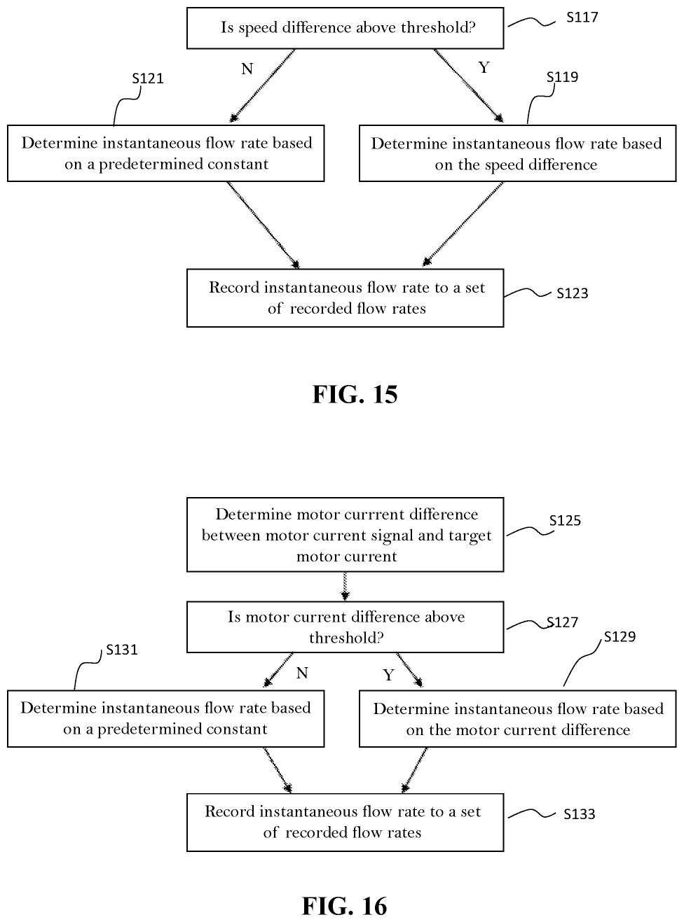

Moving to FIG. 14, the controller 206 may additionally, at any time after step S101, determine an instantaneous flow rate of ground coffee between a current discrete position and a previous discrete position of the grinding element 202. For example, the instantaneous flow rate may be measured in grams-per-position-increment and be indicative of how many grams of ground coffee are manufactured by a rotation of the grinding element 202 from one discrete position to the next discrete position. In another example the instantaneous flow rate is determined relative to a predetermined target instantaneous flow rate, for example as a percentage or as a difference of the target instantaneous flow rate. For example, the controller may record an instantaneous amount of ground coffee that has been ground by the grinder at each interval and store a value (e.g. per unit volume) associated with the amount of ground coffee in an array in memory. The total amount ground can be determined from the stored array to determine when a defined amount of coffee has been ground and to stop the grinding process upon the determination that the defined amount has been ground. This provides a very accurate way to measure the actual amount of coffee that has been ground. As seen in FIG. 15, the present disclosure contemplates two methods of determining the instantaneous flow rate.

At step S119, the controller 206 assigns a predetermined constant as the instantaneous flow rate. In situations where a magnitude of the speed difference is below a predetermined threshold, the instantaneous flow rate can be known for the grinder 200, being the target instantaneous flow rate, and does not vary. Thus the predetermined constant is used by the controller 206 as the instantaneous flow rate.

If, however, the magnitude of the speed difference is above the predetermined threshold, the instantaneous flow rate fluctuates as a function of the speed difference. Thus, at step S121, the controller 206 may determine the instantaneous flow rate based on the speed difference. One example of a function that may be used is:

Qᵢₙₛ=K₂×(1+K₃×v_{target}−vᵢₙₛ)

where:
Qᵢₙₛ: Instantaneous flow rate (absolute or relative to target instantaneous flow rate).
K₂, K₃: Constants determined by design parameters of the grinder 200.
v_{target}: Predetermined target motor speed.
vᵢₙₛ: Speed derived from speed signal.

At step S117 the processor 206 determines if the magnitude of the speed difference is above the predetermined threshold, and moves to step S119 if the magnitude is not above the threshold, or to step S121 if the magnitude is below the threshold. In either scenario, the instantaneous flow rate is, at step S123, recorded by the processor 206 to a set of recorded flow rates. Preferably, each instantaneous flow rate is determined at fixed time intervals, or recorded with a time stamp, or determined at, or shortly after, every time (or by a predetermined pattern determined by) the position signal indicates a change in position of the grinding element.

At step S115, the processor 206 determines a total amount of ground coffee manufactured based on the set of recorded flow rates. For example, the processor 206 might integrate, or sum, the set of recorded flow rates over their time stamp or signal. Alternatively, in the preferred embodiment the instantaneous flow rates are recorded as grams-per-discrete-position-increment, and may thus be simply added together to yield the total amount of ground coffee manufactured. Alternatively, the processor 206 may simply count the number of discrete position changes, this method may be accurate enough if the instantaneous flow rate is previously known, and is especially accurate if the magnitude of the speed difference remained below the threshold for substantially the entire grinding process. In another alternative, if the magnitude of the speed difference is above the threshold, the target motor turn count is proportionally decreased if the instantaneous flow rate is larger than the target instantaneous flow rate, or proportionally increased if the instantaneous flow rate is lower than the target instantaneous flow rate.

In a further embodiment, shown in FIG. 16, the controller may use the motor current sensor to determine the instantaneous flow rate. In this instance, at step S125, the controller 206 determines a magnitude of a motor current difference between the motor current signal and a predetermined target motor current. The processor 206 then, at step S127, determines whether the magnitude of the motor current difference is above a predetermined threshold. If the magnitude is below the threshold, the processor, at step S131, assigns a predetermined constant as the instantaneous flow rate. If the magnitude is above the threshold, the processor 206 determines the instantaneous flow rate based on the motor current difference. For example, one function that may be used to relate the motor current difference to the instantaneous flow rate is:

Qᵢₙₛ=K₂×(1+K₃×i_{target}−iᵢₙₛ)

where:
Qᵢₙₛ: Instantaneous flow rate.
K₂, K₃: Constants determined by design parameters of the grinder 200.
i_{target}: Predetermined target motor current.
iᵢₙₛ: Motor current derived from motor current signal.

In one embodiment, the processor 206 only uses one of the motor current signal and the position signal to determine the instantaneous flow rate. In other embodiments, the processor 206 performs both methods of determining the instantaneous flow rate.

The processor 206 may be adapted to alter the constants K₂, K₃ used in steps S129 and S121, based on changes in grinder properties of the grinder 200. For example, when changing the coarseness of the ground coffee being manufactured by the grinder 200 (that is, adjusting a clearance of the grinder 200), the constants K₂, K₃ should be adjusted. Further, a user may replace or alter the grinder 200, by changing a grinder material of the grinding element 202, or otherwise altering a geometric property of the grinder 200. The controller 206 may be adapted to receive user input of these changes and, accordingly, make adjustments to the constants K₂, K₃, such that the determination of the instantaneous flow rate is at least partially based on these properties.

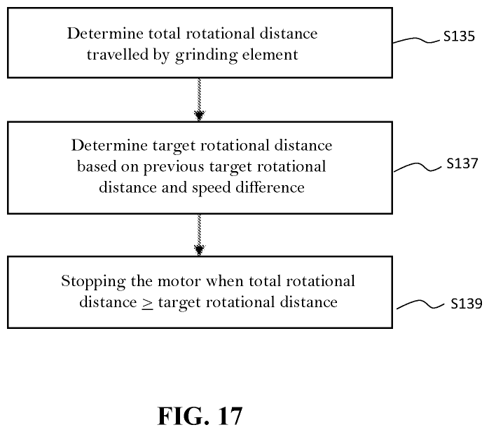

As shown in FIG. 17, the step S115 of determining the total amount of ground coffee manufactured may include, at step S135, a determination by the processor 206 of a total rotational distance travelled by the grinding element 202. This determination may be performed based on the position signal, for example by determining the number of position changes, for example by polling the motor turn counter. The processor 206 may then, at step S137 determine a target rotational distance, based on the total rotational distance already travelled, and the set of recorded flow rates, or alternatively by polling the target motor turn count, which is updated based on the previous target motor turn count and the speed difference. Naturally, the initial target motor turn count is predetermined, or initialised, by the controller 206 as discussed above. The motor turn count is thus an estimate, based on the set of recorded instantaneous flow rates and the distance over which they were achieved, of how much further the grinding element 202 should travel to achieve the target dose. This estimate is preferably updated each time the position signal indicated a change in position, by updating the target motor turn count in accordance with the method described above. At step S139, the processor 206 compares the motor turn counter to the target motor turn count and stops the motor 204 when the motor turn counter is equal to, or larger than, the target motor turn count.

Alternatively, step S139 may be performed on the basis of the set of recorded flow rates and a target dose of ground coffee to be manufactured (for example 20 grams). The processor 206 compares the total amount of ground coffee manufactured to the target dose and, if the total amount of ground coffee manufactured is equal to, or larger than, the target dose, stops the motor 204.

Advantages of the filter cup 100 will now be discussed.

Because the magnet 114 is included in the body 102, different filter cups 100 may be differentiated at a distance based on the magnetic field produced. Attaching the magnet 114 at the sidewall 108, particular the outside surface 116, provides minimal interference with the water flow paths in the cavity 112 when extracting the coffee beverage. Using the key and portafilter key ensures that the magnet 114 is oriented in a predetermined configuration when the filter cup 100 is mounted on the portafilter 150, allowing the magnetic field to be more easily read. Using the flange portion 522 to engage the protrusion 154 uses a pre-existing feature on most portafilters 150, meaning that the filter cup 100 would be retrofittable. Using the boss portion 118 allows the key to also include the magnet 114, which has manufacturing cost benefits. Using the boss portion 318 that is located at the rim 310 allows easy location of the filter cup 300 relative to the portafilter 150, as the boss portion 318 slides into location during the normal press fit motion of installing the filter cup 300.

Using a predetermined look-up table (or thresholding of values or ranges between magnetic values) allows the use of tolerancing when determining the property of the filter cup 100 by measuring the magnetic field, and reduces the processing power required involved in the step of converting the magnitude and/or direction of the magnetic field to the property of the filter cup 100. Using the magnitude and direction of the magnetic field to determine the property of the filter cup 100 allows a larger quantity of different filter cups 100 to be differentiated from one another. The use of a plurality of magnets 114 may reduce wear on any one particular magnet 114, and increases the ease of placing the filter cup 100 correctly into the portafilter 150.

The use of the portafilter processor to determine the property of the filter cup removes the orientation of the portafilter 150 relative to the espresso machine 160 as a variable and thus increases accuracy of the determination of the property of the filter cup 100. It also reduces a distance between the magnet 114 and the sensor, requiring the magnet 114 to be less powerful or of a lower grade (and therefore less expensive) and/or increasing the accuracy of the magnet signal. The user of the machine processor centralises all tasks in a single processor and thus reduces manufacturing costs of the portafilter 150. When used with retrofittable filter cups 100, such as those including the flange portion 522, the espresso machine 160 is also compatible with portafilters 150 not including the portafilter processor.

The modification of the machine parameters based on the property of the filter cup 100 removes a user input step in the extraction of a coffee beverage and may eliminate user input error that occurs in this step. The use of predetermined extraction profiles containing the machine parameters, particular when modified by user input, may allow multiple users to use the same espresso machine 160 with their personally preferred extraction profile associated with different filter cups 100.

The advantageous embodiments and/or further developments of the above disclosure—except for example in cases of clear dependencies or inconsistent alternatives—can be applied individually or also in arbitrary combinations with one another. For example, the sensor 172 and machine processor may be located in a stand-alone grinder having machine parameters including a grind time, a grind weight, a grind size, and/or a set of tamping parameters. The filter cup 100, located in the portafilter 150 as disclosed above, may then be held in the grinder fitting 170 of the stand-alone grinder. The operation of the machine processor, the sensor, and the stand-alone grinder is substantially the same as described in relation to the espresso machine 160 having an integrated grinder. Similarly, the portafilter 150 may include the portafilter processor and the sensor 172, in which case the stand-alone grinder does not include the sensor 172.

Advantages of the grinder 200 and the method 250 will now be discussed.

Because the motor 204 is operated by the controller 206 at the second motor speed based on the position signal, the grinding element 202 is more likely to operate at a constant, target, speed, even if the load on the grinding element 202 changes due to the discrete nature of the coffee beans being ground. The use of the motor shaft position sensor allows the measurement of speed at the motor shaft 210, which usually operates at a higher speed than the grinding element 202, and thus easier to measure precisely. The use of 6 discrete positions is an efficient middle ground between a more detailed position signal, and additional components, and therefore rotational inertia, attached to the motor shaft 210. The use of a hall effect sensor allows the use of magnets to denote the discrete positions, which is a cost-effective component. Operating the motor 204 on the basis of the motor current signal removes the need for a position signal, or alternatively improves the determination of the second speed.

Because the processor 206 determines an instantaneous flow rate, the processor 206 can take into account small fluctuations in the instantaneous flow rate when calculating the total amount of ground coffee manufactured. This desirably results in more precise information about the total amount of ground coffee manufactured and allows the processor 206 to stop the motor 204 at a more precise moment in time. The determination of the instantaneous flow rate based on the speed difference, allows the processor 206 to estimate the instantaneous flow rate when the grinding element 202 operates above or below an intended design speed of the grinding element 202 due to load fluctuations caused by the discrete nature of coffee beans. By configuring the processor 206 to determine whether speed signal indicates that the grinding element 202 is operating within design parameters, or outside design parameters, allows the processor 206 to only conduct the processing-time-intensive approximation calculation if and when required. The use of the motor current signal to determine the instantaneous flow rate may remove the need for the grinder position sensor 208, or improve the precision of the determination of the instantaneous flow rate. Changing the constants in the determination of the instantaneous flow rate allows the processor 206 to adapt the function in response to changes in the grinder properties, such as a change in desired coarseness of the ground coffee.

Determining the target rotational distance allows the processor 206 to consider fluctuations of the instantaneous flow rate, recorded in the set of recorded flow rates, to determine a desirable total rotational distance travelled to achieve the target dose of ground coffee. Similarly, calculating the total amount of ground coffee manufactured based on the recorded flow rates may be used to stop the motor 204 more precisely.

Reference Numerals:

| | |
|---|---|
| 100 | filter cup |
| 102 | body |
| 104 | floor |
| 106 | perforations |
| 108 | sidewall |
| 110 | rim |
| 112 | cavity |
| 114 | magnet |
| 116 | outside surface of sidewall |
| 118 | boss portion |
| 126 | magnet axis |
| 128 | central axis |
| 150 | portafilter |
| 152 | recess |
| 154 | protrusion |
| 160 | espresso machine |
| 162 | engagement face of the spring plate |
| 164 | machine processor |
| 166 | user interface |
| 168 | extraction fitting |
| 170 | grinder fitting |
| 172 | sensor (magnetometer) |
| 175 | top channel |
| 176 | bottom channel |
| 177 | sensor housing |
| 178 | spring plate |
| 179 | fasteners |
| 180 | peripheral configuration of raised enagagement face |
| 200 | grinder |
| 202 | grinding element |
| 204 | motor |
| 206 | controller |
| 208 | grinder position sensor |
| 210 | motor shaft |
| 212 | motor shaft axis |
| 300 | filter cup |
| 308 | sidewall |
| 310 | base |
| 311 | hopper |
| 312 | recess |
| 313 | head |
| 314 | front panel |
| 315 | adjustment rotating knob |
| 316 | present amount button |
| 317 | start/cancel button |
| 318 | grind size selector dial |
| 319 | external button |
| 320 | display |
| 321 | grind size index line |
| 322 | enclosure for magnet |
| 323 | 1^{st} gradient line |
| 324 | retainment space |
| 325 | 2^{nd} gradient line |
| 326 | first flap |
| 327 | second flap |
| 328 | 1st sidewall |
| 329 | 2nd sidewall |
| 330 | 3rd sidewall |
| 331 | 4th sidewall |
| 333 | numeric display portion |
| 334 | spot weld location |
| 410 | base |
| 411 | upright portion |
| 412 | ledge |
| 413 | removable tamper |
| 414 | portafilter support cradle |
| 415 | brew head |
| 416 | user controls |
| 417 | pressure gauge |
| 418 | indicators |
| 419 | removable bean hopper |
| 461 | lower burr |
| 462 | upper burr |
| 463 | gearbox |
| 464 | drive gear |
| 465 | teeth |
| 466 | driven gear |
| 467 | fine threads on internal bore |
| 468 | fine threads on outside surface |
| 469 | carriage |
| 470 | grinder housing |
| 471 | tabs |
| 472 | tooth |
| 473 | rim |
| 474 | jaws |
| 475 | web section |
| 477 | male bayonet element |
| 478 | female bayonet element |
| 479 | U-shaped handle |
| 480 | ears |
| 481 | rim |
| 482 | top flange |
| 483 | lower section of reduced diameter |
| 484 | external gear ring |
| 485 | radially oriented gear teeth |
| 486 | pinion gear |
| 487 | potentiometer |
| 488 | potentiometer outputs |
| 522 | flange portion |
| 524 | recess |

1. A filter cup for holding ground coffee for use with a portafilter to extract coffee, the filter cup including a body having:
a floor with a plurality of perforations;
a sidewall extending upwardly from the floor to a rim to define a cavity for holding the ground coffee; and
a magnet attached to the body for producing a magnetic field.

2. The filter cup of claim 1, wherein the magnet is attached to the floor.

3. The filter cup of claim 1, wherein the magnet is attached to the sidewall.

4. The filter cup of claim 3, wherein the magnet is attached to an outside surface of the sidewall.

5. The filter cup of claim 1, wherein the body has a key adapted to engage, when the filter cup is mounted on the portafilter, a corresponding portafilter key on the portafilter such that the filter cup is mountable on the portafilter in a predetermined configuration.

6. The filter cup of claim 5, wherein the key includes a flange portion of the rim that extends downwardly from the rim and the portafilter key includes a protrusion on the portafilter.

7. The filter cup of claim 5, wherein the key includes a boss portion located on the sidewall and extending outwardly therefrom and the portafilter key includes a recess in the portafilter for receiving the boss portion.

8. The filter cup of claim 7, wherein the boss portion includes the magnet.

9. The filter cup of claim 1, wherein the magnet has a predetermined property that influences the magnetic field produced by the magnet, for matching a property of the filter cup to be determined by measuring the magnetic field and reference a predetermined look-up table.

10. The filter cup of claim 9, wherein the predetermined property includes one or more of:
a direction of a magnet axis of the magnet relative to a central axis of the filter cup; and
a strength of the magnet.

11. The filter cup according to any one of claims 1 to 10, further comprising an enclosure for housing the magnet, the housing having a retainment space for receiving the magnet, and at least one flap for securing the enclosure to the filter cup.

12. The filter cup according to claim 11, wherein the flap is secured to the filter cup by spot welding.

13. The filter cup of claim 1, wherein the body has a plurality of magnets.

14. A portafilter holding the filter cup of any one of claims 1 to 13.

15. The portafilter of claim 14, the portafilter further including:
a sensor for determining a magnitude and/or direction of the magnetic field produced by the magnet and adapted to produce a magnet signal indicative of the magnitude and/or direction of the magnetic field;
a portafilter processor adapted to:
receive the magnet signal;
determine a property of the filter cup based on the magnet signal; and
produce a filter cup signal indicative of a property of the filter cup; and
a communication module adapted to:
receive the filter cup signal; and
transmit the filter cup signal to a receiver module.

16. The portafilter of claim 15, wherein the sensor is a Hall effect sensor.

17. The portafilter of claim 15, wherein the sensor is a magnetometer.

18. An espresso machine used with the portafilter of claim 14.

19. The espresso machine of claim 18, wherein the espresso machine includes:
a sensor for determining a magnitude and/or direction of the magnetic field produced by the magnet and producing a magnet signal indicative of the magnitude and/or direction of the magnetic field;
a machine processor adapted to:
receive the magnet signal;
determine a property of the filter cup based on the magnet signal; and
modify one or more of the following machine parameters based on the property of the filter cup:
a ground coffee quantity;
a brewing pressure setting or profile;
a brewing temperature
a pre-infusion period;
a water quantity; and
a water flow rate.

20. An espresso machine used with the portafilter of claim 15 or 16, wherein the receiver module is mounted in the espresso machine and the espresso machine further includes:
a machine processor adapted to:
receive the filter cup signal; and
modify one or more of the following machine parameters of the espresso machine based on the filter cup signal:
a ground coffee quantity;
a brewing pressure setting or profile;
a pre-infusion period;
a water quantity; and
a water flow rate.

21. The espresso machine of claim 19 or claim 20, wherein the espresso machine further includes:
a memory module in communication with the machine processor and containing a database of predetermined extraction profiles, each associated with a predetermined set of filter cup properties, each extraction profile containing information relating to one or more of the following machine parameters:
a ground coffee quantity;
a brewing pressure setting or profile;
a pre-infusion period;
a water quantity; and
a water flow rate;
and wherein the machine processor is adapted to access the database and modify the machine parameters of the espresso machine to coincide with a particular extraction profile that corresponds to a particular filter cup property or set of properties determined by measuring the magnetic field produced by the magnet.

22. The espresso machine of claim 21, wherein the espresso machine includes a user interface in communication with the machine processor and the machine processor is adapted to modify the extraction profile based on a user input received at the user interface.

23. A standalone grinder used with the portafilter of claim 14 or claim 15.
